(19) United States
(12) Patent Application Publication
(10) Pub. No.: US 2025/0143154 A1
(43) Pub. Date: May 1, 2025

(54) SEMICONDUCTOR DEVICE WITH LIGHT-SHIELDING LAYER AND FABRICATING METHOD OF THE SAME

(71) Applicant: UNITED MICROELECTRONICS CORP., Hsin-Chu City (TW)

(72) Inventor: Shin-Hung Li, Nantou County (TW)

(73) Assignee: UNITED MICROELECTRONICS CORP., Hsin-Chu City (TW)

(21) Appl. No.: 18/509,320

(22) Filed: Nov. 15, 2023

(30) Foreign Application Priority Data
Oct. 31, 2023 (TW) 112141787

(51) Int. Cl. H10K 59/80; H10K 71/20; H10K 71/60

(52) U.S. Cl. CPC H10K 59/8792; H10K 71/231; H10K 71/60

(57) ABSTRACT

A semiconductor device with a light-shielding layer includes a dielectric layer. A conductive plug penetrates the dielectric layer. A first anode is disposed on a top surface of the dielectric layer and the first anode contacts an end of the conductive plug. A light-shielding layer is embedded in the dielectric layer, wherein the light-shielding layer is located at one side of the conductive plug and a top surface of the light-shielding layer is aligned with the end of the conductive plug. The light-shielding layer includes titanium nitride, silver, aluminum, silicon nitride, silicon carbon nitride or silicon oxynitride. A switching element is electrically connected to the conductive plug.

### BACKGROUND OF THE INVENTION

### 1. Field of the Invention

The present invention relates to a semiconductor device with a light-shielding layer, and in particular to a semiconductor device using a light-shielding layer to block light from an organic light-emitting diode (OLED).

### 2. Description of the Prior Art

With the advent of the information society, the display field has developed rapidly with the increasing interest in information displays for processing and displaying large amounts of information and the increased demand for portable information media. Therefore, various thin and light panels have been developed. Among flat display devices, organic light emitting diode (OLED) displays are self-luminous displays and do not require a backlight unit used in a liquid crystal display (LCD). Therefore, the OLED displays can be light and have a thin profile.

In addition, comparing with LCD displays, OLED displays have advantages in viewing angle, contrast and power consumption. Moreover, the OLED display can be driven by a low direct current (DC) voltage and can have a fast response speed. Furthermore, since the internal elements of the OLED display are solid-state, the OLED display can resist external impact and has a large operating temperature range. Because OLED displays are manufactured through a simple process, manufacturing costs can be reduced compared with traditional liquid crystal displays. However, the light generated in the OLED may be unintentionally guided to the signal control unit disposed below the OLED. In particular, the light may affect active components in the signal control unit.

### SUMMARY OF THE INVENTION

In view of this, the present invention specifically provides a light-shielding layer on one side of the OLED to block the light of the OLED.

According to a preferred embodiment of the present invention, a semiconductor device with a light-shielding layer includes a dielectric layer. A conductive plug penetrates the dielectric layer. A first anode is disposed on a top surface of the dielectric layer and the first anode contacts an end of the conductive plug. A light-shielding layer is embedded in the dielectric layer, wherein the light-shielding layer is disposed at one side of the conductive plug, a top surface of the light-shielding layer is aligned with the end of the conductive plug, and the light-shielding layer includes titanium nitride, silver, aluminum, silicon nitride, silicon carbon nitride or silicon oxynitride. A switching element electrically connects to the conductive plug.

According to another preferred embodiment of the present invention, A fabricating method of a semiconductor device with a light-shielding layer includes providing a dielectric layer. Next, the dielectric layer is etched to form a trench. Later, the dielectric layer is etched to form a contact hole. Subsequently, a titanium nitride layer is formed to cover the contact hole and the trench. After that, a tungsten layer is formed to fill in the contact hole and the trench. Next, the tungsten layer and the titanium nitride layer outside of the trench and the contact hole are removed. Finally, an anode is formed to contact the tungsten layer and the titanium nitride layer in the contact hole.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 depict a fabricating method of a semiconductor device with a light-shielding layer according to a first preferred embodiment of the present invention, wherein:

FIG. 1 depicts a material layer with conductive pads thereon;

FIG. 2 is a fabricating stage in continuous of FIG. 1;

FIG. 3 is a fabricating stage in continuous of FIG. 2;

FIG. 4 is a fabricating stage in continuous of FIG. 3; and

FIG. 5 is a fabricating stage in continuous of FIG. 4.

FIG. 6 depicts a modified light-shielding layer according to another preferred embodiment of the present invention.

FIG. 7 to FIG. 9 depict a fabricating method of a semiconductor device with a light-shielding layer according to a second preferred embodiment of the present invention, wherein:

FIG. 7 depicts a material layer with conductive pads thereon;

FIG. 8 is a fabricating stage in continuous of FIG. 7; and

FIG. 9 is a fabricating stage in continuous of FIG. 8.

FIG. 10 depicts a semiconductor device with a light-shielding layer according to a third preferred embodiment of the present invention.

### DETAILED DESCRIPTION

FIG. 1 to FIG. 5 depict a fabricating method of a semiconductor device with a light-shielding layer according to a first preferred embodiment of the present invention. FIG. 6 depicts a modified light-shielding layer according to another preferred embodiment of the present invention.

As shown in FIG. 1, a material layer 10 is provided. The material layer 10 is formed by stacking a semiconductor substrate and a dielectric layer. The semiconductor substrate includes a silicon substrate, a germanium substrate, a gallium arsenide substrate, a silicon germanium substrate, an indium phosphide substrate, a gallium nitride substrate, a carbide substrate or a silicon-on-insulator substrate. The dielectric layer includes silicon oxide, silicon nitride, silicon oxynitride or other insulating materials. Numerous switching elements and conductive pads are arranged in the material layer 10. For example, switching elements T1/T2 and conductive pads 12a/12b are disposed in the material layer 10. The top surfaces of the conductive pads 12a/12b are aligned with the top surface of the material layer 10. Each of the conductive pads 12a/12b electrically connects to a source/drain of each of the switching elements T1/T2. Then, a dielectric layer 14 is formed to cover and contact the material layer 10. Later, a dielectric layer 10 is etched to form at least one trench 16.

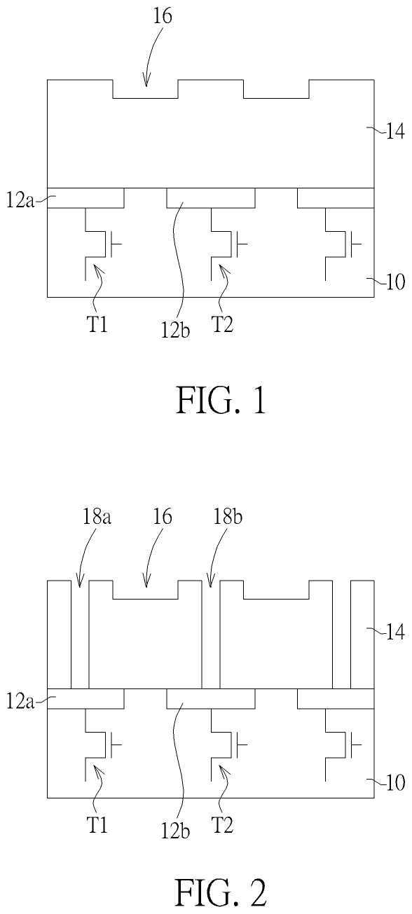

As shown in FIG. 2, a mask (not shown) is formed to cover the trench 16. The dielectric layer 14 is then etched to form contact holes 18a/18b penetrating the dielectric layer 14 and exposing the conductive pads 12a/12b. Contact holes 18a/18b are adjacent to trench 16. Subsequently, the mask is removed. As shown in FIG. 3, a titanium nitride layer 20 is formed to cover the sidewalls of the contact holes 18a/18b and the bottom and the sidewall of the trench 16. Later, a tungsten layer 22 is formed to fill in the contact holes 18a/18b and the trench 16 and cover the dielectric layer 14. The titanium nitride layer 20 directly contacts the sidewalls of the contact holes 18a/18b, and the bottom and sidewall of the trench 16. The tungsten layer 22 directly contacts the titanium nitride layer 20. The titanium nitride layer 20 and the tungsten layer 22 are formed by sputtering, a physical vapor deposition, a chemical vapor deposition or an atomic layer deposition.

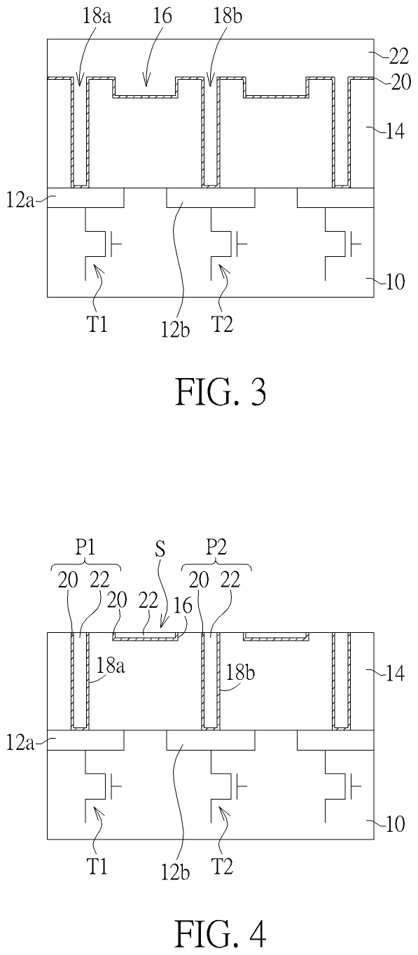

As shown in FIG. 4, the tungsten layer 22 and the titanium nitride layer 20 outside of the contact holes 18a/18b and the trench 16 are removed, and the removing process can be a polishing process. Now, the tungsten layer 22 and titanium nitride layer 20 remaining in the contact holes 18a/18b form conductive plugs P1/P2. The titanium nitride layer 20 in the contact holes 18a/18b serves as a barrier to prevent tungsten atoms from diffusing into the dielectric layer 14 from the contact holes 18a/18b. In addition, because titanium nitride has the property of absorbing light, the titanium nitride layer 20 remaining in the trench 16 can be used as light-shielding material. The tungsten layer 22 remaining in the trench 16 is not light-shielding material. In this embodiment, because the light-shielding material in the light-shielding layer S can provide enough light-shielding effect, even the light-shielding layer S include both light-shielding material and non-light shielding material, the light-shielding layer S can still block light well. According to another preferred embodiment of the present invention, as shown in FIG. 6, after removing the tungsten layer 22 and the titanium nitride layer 20 outside of the contact holes 18a/18b and the trench 16, the polishing process can continue until the tungsten layer 22 in the trench 16 is completely removed. In this way, only the titanium nitride layer 20 remains in the trench 16 and there is no tungsten layer 22 in the trench 16.

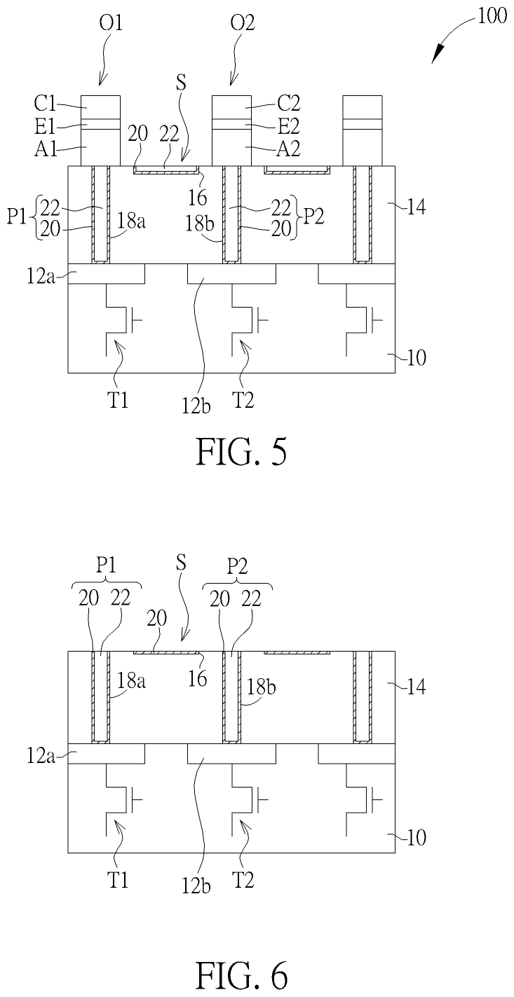

FIG. 5 depicts steps in continuous of FIG. 4. As shown in FIG. 5, anodes A1/A2 are formed on the top surface of the dielectric layer 14. The anodes A1/A2 respectively contact the tungsten layer 22 and the titanium nitride layer 20 in the contact holes 18a/18b. In details, the anode A1 contacts the conductive plug P1, and the anode A2 contacts the conductive plug P2. However, the anodes A1/A2 do not contact the tungsten layer 22 and titanium nitride layer 20 in the trench 16. That is, the anodes A1/A2 do not contact the light-shielding layer S. Later, emitting layers E1/E2 and cathodes C1/C2 are formed in sequence to respectively cover the anodes A1/A2. The anode A1, the emitting layer E1 and the cathode C1 form an OLED O1. The anode A2, the emitting layer E2 and the cathode C2 form an OLED O2. The anodes A1/A2 and the cathodes C1/C2 may respectively include copper, aluminum or tungsten. Now, a semiconductor device with a light-shielding layer 100 of the present invention is completed. In addition, according to different requirements, the number of conductive plugs P1/P2, the OLEDs O1/O2 and the light-shielding layer S can be adjusted.

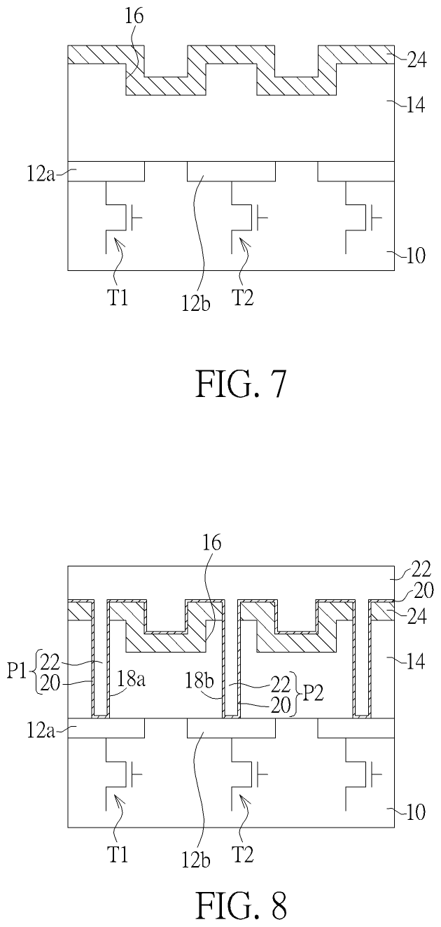

FIG. 7 to FIG. 9 depict a fabricating method of a semiconductor device with a light-shielding layer according to a second preferred embodiment of the present invention, wherein elements which are substantially the same as those in the first preferred embodiment are denoted by the same reference numerals; an accompanying explanation is therefore omitted.

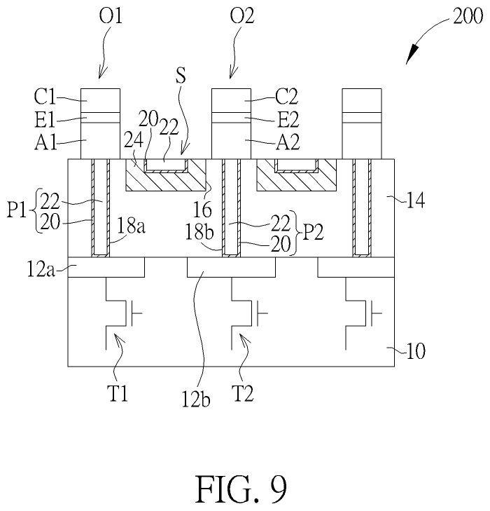

FIG. 7 depicts steps in continuous of FIG. 1. As shown in FIG. 7, a nitrogen-containing material layer 24 is formed to cover the dielectric layer 14 and the trench 16. The nitrogen-containing material layer 24 contacts the sidewall and bottom of trench 16. The nitrogen-containing material layer 24 includes silicon nitride, silicon nitride carbide or silicon oxynitride. As shown in FIG. 8, the nitrogen-containing material layer 24 and dielectric layer 10 are etched to form contact holes 18a/18b. Then, a titanium nitride layer 20 and a tungsten layer 22 are formed sequentially to cover the contact holes 18a/18b and the trench 16. The difference between the first preferred embodiment and the second preferred embodiment is that in the second preferred embodiment, the titanium nitride layer 20 in trench 16 contacts the nitrogen-containing material layer 24. As shown in FIG. 9, the tungsten layer 22, the titanium nitride layer 20 and the nitrogen-containing material layer 24 outside of the trench 16 and the contact holes 18a/18b are removed. Now, the tungsten layer 22 and titanium nitride layer 20 remaining in the contact holes 18a/18b form conductive plugs P1/P2. In addition, the titanium nitride layer 20 and the nitrogen-containing material layer 24 both have light-absorbing properties, so the nitrogen-containing material layer 24 and the titanium nitride layer 20 remaining in the trench 16 serve as light-shielding materials. The following steps are the same as that in FIG. 5. That is, emitting layers E1/E2 and cathodes C1/C2 are formed in sequence to respectively cover the anodes A1/A2. Now, a semiconductor device with a light-shielding layer 200 of the present invention is completed.

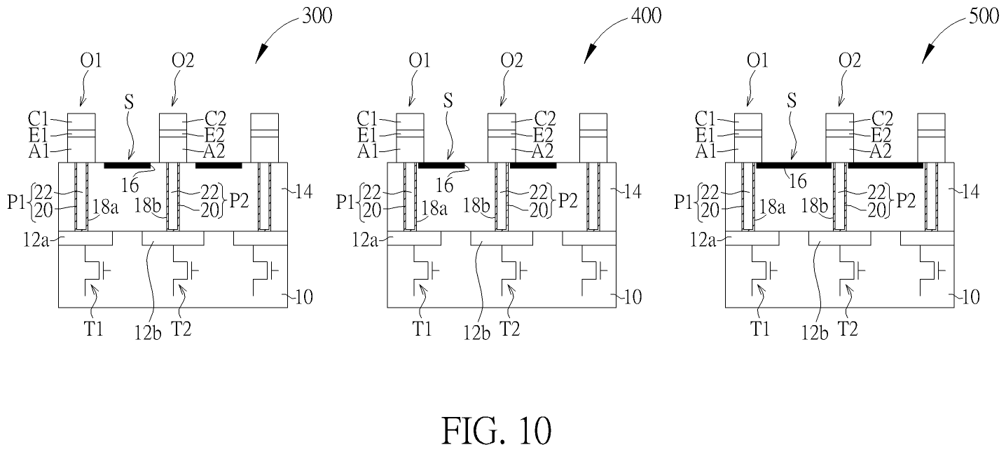

FIG. 10 depicts a semiconductor device with a light-shielding layer according to a third preferred embodiment of the present invention, wherein elements which are substantially the same as those in the first preferred embodiment are denoted by the same reference numerals; an accompanying explanation is therefore omitted.

As shown in FIG. 10, a semiconductor device with a light-shielding layer 300 includes a dielectric layer 14. Conductive plugs P1/P2 penetrate the dielectric layer 14. OLEDs O1/O2 are disposed on the dielectric layer 14. The OLED O1 is formed of the anode A1, the light-emitting layer E1 and the cathode C1. The OLED O2 is formed of the anode A2, the light-emitting layer E2 and the cathode C2. The anodes A1/A2 are disposed on the top surface of the dielectric layer 14, the anode A1 contacts one end of the conductive plug P1, and the anode A2 contacts one end of the conductive plug P2. Two light-shielding layers S are embedded in the dielectric layer 14. The light-shielding layers S are respectively located at one side of the conductive plugs P1/P2 and the top surfaces of the light-shielding layers S are aligned with the end of the conductive plug P1 and the end of the conductive plug P2. The light-shielding layers S are all below the anodes A1/A2. In this embodiment, the light-shielding layers S do not contact or overlap the anodes A1/A2. The light-shielding layers S do not contact any conductive plug. The light-shielding layers S include titanium nitride, silver, aluminum, silicon nitride, silicon carbide nitride or silicon oxynitride. The light-shielding layers S are floating. That is, the light-shielding layers S do not electrically connect to other devices or metal line. In details, each of the light-shielding layers S includes a trench 16 and a light-shielding material filling in the trench 16. Based on different manufacturing processes, each of the light-shielding layers S may further include non-light-shielding material. The light-shielding material may be selected at least one or more than one from the group consisting of titanium nitride, silver, aluminum, silicon nitride, silicon carbide nitride and silicon oxynitride. For example, as shown in FIG. 5, the light-shielding material in the light-shielding layer S is the titanium nitride layer 20. Since the light-shielding layer S and the conductive plugs P1/P2 are made by using the same process, there is a non-light-shielding material (tungsten layer 22) disposed on the light-shielding material. In other way, as shown in FIG. 6, the light-shielding material in the light-shielding layer S is a titanium nitride layer 20, and the tungsten layer 22 is entirely removed during the polishing process. Therefore, there is only light-shielding material (titanium nitride layer 20) in the light-shielding layer S. On the other hand, as shown in FIG. 9, the light-shielding materials in the light-shielding layer S include the nitrogen-containing material layer 24 and the titanium nitride layer 20. The nitrogen-containing material layer 24 contacts the trench 16, and the titanium nitride layer 20 and the tungsten layer 22 are surrounded by the nitrogen-containing material layer 24. The nitrogen-containing material layer 24 includes silicon nitride, silicon carbide nitride or silicon oxynitride. To put it simply, the light-shielding layer S must have at least one light-shielding material, and non-light-shielding material is optionally provided. The position of the light-shielding material in the trench 16 can be adjusted as requirements.

Please refer to FIG. 10 again. The conductive pads 12a/12b in the semiconductor device with a light shielding layer 300 respectively contact the other end of each of the conductive plugs P1/P2. The conductive pads 12a/12b are electrically connected to a source/drain of each of the switching elements T1/T2 so as to make the switching elements T1/T2 respectively control the OLEDs O1/O2. The conductive plug P1 includes a contact hole 18a, a titanium nitride layer 20 and a tungsten layer 22. The conductive plug P2 includes a contact hole 18b, a titanium nitride layer 20 and a tungsten layer 22. The titanium nitride layer 20 contacts the sidewalls of the contact holes 18a/18b.

Since titanium nitride, silicon nitride, silicon carbide nitride and silicon oxynitride have light-absorbing properties, and silver and aluminum have light-reflecting properties, when the light-shielding layer S includes one or more than one of the material containing titanium nitride, silver, aluminum, silicon nitride, silicon nitride carbide or silicon oxynitride, the light-shielding layer S can reflect light or absorb light. In the present invention, the light-shielding layer S is specially disposed between the OLED O1 and OLED O2. In this way, light from the OLEDs O1/O2 can be blocked or reflected. This keeps the light of the OLEDs O1/O2 from entering the components in the material layer 10, thereby preventing the performance of the components from being affected by light.

Please still refer to FIG. 10. The difference between the semiconductor device with a light-shielding layer 400 and the semiconductor device with a light-shielding layer 300 is that one side of the light-shielding layer S of the semiconductor device with a light-shielding layer 400 contacts and overlaps the anode A1, but the other side of the light-shielding layer S does not contact anode A2. In addition, in the semiconductor device with a light-shielding layer 500, two sides of the light-shielding layer S respectively contact the anode A1 and the anode A2 and overlap the anodes A1/A2. In order to prevent the anode A1 couples to the anode A2, the part of the light-shielding layer S that contacts the anode A1 and the anode A2 needs to be non-conductive material. Among light-shielding materials which are non-conductive material include silicon nitride, silicon carbide nitride and silicon oxynitride, and they can be used as non-conductive material in the light-shielding layer S. The part of the light-shielding layer S that does not contact the anode A1 and anode A2 can be selected from all possible light-shielding materials. Because the part that contacts the anode A1 and the anode A2 uses light-shielding materials, the part that does not contact the anodes A1/A2 can use non-light-shielding materials, such as tungsten or copper.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device with a light-shielding layer, comprising:
a dielectric layer;
a conductive plug penetrating the dielectric layer;
a first anode disposed on a top surface of the dielectric layer and the first anode contacting an end of the conductive plug;
a light-shielding layer embedded in the dielectric layer, wherein the light-shielding layer is disposed at one side of the conductive plug, a top surface of the light-shielding layer is aligned with the end of the conductive plug, and the light-shielding layer comprises titanium nitride, silver, aluminum, silicon nitride, silicon carbon nitride or silicon oxynitride; and
a switching element electrically connecting to the conductive plug.

2. The semiconductor device with a light-shielding layer of claim 1, wherein an entirety of the light-shielding layer is disposed under the first anode.

3. The semiconductor device with a light-shielding layer of claim 1, further comprising:
an emitting layer covering the first anode;
a cathode disposed on the emitting layer, wherein the first anode, the emitting layer and the cathode form an organic light-emitting diode (OLED).

4. The semiconductor device with a light-shielding layer of claim 1, wherein the light-shielding layer comprises titanium nitride, silver or aluminum, and the light-shielding layer does not contact the first anode and does not overlap the first anode.

5. The semiconductor device with a light-shielding layer of claim 1, wherein the light-shielding layer comprises silicon nitride, silicon carbide nitride or silicon oxynitride, and the light-shielding layer contacts and overlaps the first anode.

6. The semiconductor device with a light-shielding layer of claim 1, wherein the light-shielding layer comprises:
a trench;
a titanium nitride layer contacting a bottom of the trench and a sidewall of the trench; and
a tungsten layer filling in the trench.

7. The semiconductor device with a light-shielding layer of claim 6, wherein the conductive plug comprises:
a contact hole penetrating the dielectric layer;
the titanium nitride layer contacting a sidewall of the contact hole; and
the tungsten layer filling in the contact hole.

8. The semiconductor device with a light-shielding layer of claim 1, further comprising:
a conductive pad contacting another end of the conductive plug, wherein the conductive pad electrically connecting to a source/drain of the switching element.

9. The semiconductor device with a light-shielding layer of claim 1, wherein the light-shielding layer comprises:
a trench;
a silicon nitride layer contacting a bottom of the trench and a sidewall of the trench;
a tungsten layer filling in the trench; and
a titanium nitride layer disposed between the silicon nitride layer and the tungsten layer.

10. The semiconductor device with a light-shielding layer of claim 9, wherein the silicon nitride layer of the light-shielding layer contacts the first anode and overlaps the first anode.

11. The semiconductor device with a light-shielding layer of claim 1, wherein light-shielding layer is floating.

12. The semiconductor device with a light-shielding layer of claim 1, further comprising a second anode disposed on the top surface of the dielectric layer, wherein the second anode is adjacent to the first anode, and the light-shielding layer contacts the first anode and the second anode.

13. The semiconductor device with a light-shielding layer of claim 1, further comprising a second anode disposed on the top surface of the dielectric layer, wherein the second anode is adjacent to the first anode, and the light-shielding layer only contacts the first anode and does not contact the second anode.

14. A fabricating method of a semiconductor device with a light-shielding layer, comprising:
providing a dielectric layer;
etching the dielectric layer to form a trench;
etching the dielectric layer to form a contact hole;
forming a titanium nitride layer to cover the contact hole and the trench;
forming a tungsten layer filling in the contact hole and the trench;
removing the tungsten layer and the titanium nitride layer outside of the trench and the contact hole; and
forming an anode contacting the tungsten layer and the titanium nitride layer in the contact hole.

15. The fabricating method of a semiconductor device with a light-shielding layer of claim 14, further comprising: before forming the contact hole, forming a silicon nitride layer to cover the dielectric layer and the trench.

16. The fabricating method of a semiconductor device with a light-shielding layer of claim 15, wherein steps of forming the contact hole comprise etching the silicon nitride layer followed by etching the dielectric layer.

17. The fabricating method of a semiconductor device with a light-shielding layer of claim 15, wherein the titanium nitride layer covers the silicon nitride layer.

18. The fabricating method of a semiconductor device with a light-shielding layer of claim 15, further comprising:
forming an emitting layer covering the first anode; and
forming a cathode disposed on the emitting layer, wherein the first anode, the emitting layer and the cathode form an organic light-emitting diode (OLED).
